(19) United States
(12) Patent Application Publication
(10) Pub. No.: US 2015/0263117 A1
(43) Pub. Date: Sep. 17, 2015

(54) SEMICONDUCTOR DEVICE AND MANUFACTURING METHOD THEREOF

(71) Applicant: KABUSHIKI KAISHA TOSHIBA, Minato-ku (JP)

(72) Inventors: Koichi KATO, Yokohama-shi (JP); Takao MARUKAME, Chuo-ku (JP); Yoshifumi NISHI, Yokohama-shi (JP); Yuichiro MITANI, Miura-gun (JP); Takahisa KANEMURA, Yokohama-shi (JP); Kazuya OHUCHI, Yokohama-shi (JP)

(73) Assignee: KABUSHIKI KAISHA TOSHIBA, Minato-ku (JP)

(21) Appl. No.: 14/484,685

(22) Filed: Sep. 12, 2014

Related U.S. Application Data
(60) Provisional application No. 61/952,490, filed on Mar. 13, 2014.

(51) Int. Cl. H01L 29/45; H01L 29/66; H01L 29/788; H01L 21/283; H01L 21/265

(52) U.S. Cl. CPC H01L 29/456; H01L 21/283; H01L 21/26506; H01L 29/788; H01L 29/66825

(57) ABSTRACT

A semiconductor device according to an embodiment comprises: a gate insulating film formed on a semiconductor substrate; a semiconductor layer formed on the gate insulating film; and a first metal layer formed to be electrically connected to the semiconductor layer. 1×10¹⁹ atoms/cm³ or more of a Group VI element exists in an interface of the semiconductor layer and the first metal layer.

### CROSS REFERENCE TO RELATED APPLICATIONS

This application is based on and claims the benefit of priority from prior U.S. Provisional Patent Application No. 61/952,490, filed on Mar. 13, 2014, the entire contents of which are incorporated herein by reference.

### BACKGROUND

1. Field

Embodiments described below relate to a semiconductor device and a manufacturing method thereof.

2. Description of the Related Art

A NAND type flash memory is known as a nonvolatile semiconductor memory device which is electrically rewritable and highly integrated. A memory cell of the NAND type flash memory includes a charge accumulation layer formed on a semiconductor substrate via a tunnel insulating film and a control gate stacked on the charge accumulation layer via an inter-gate insulating film. The memory cell stores data in a nonvolatile manner by a charge accumulation state of the charge accumulation layer.

In a semiconductor device such as this NAND type flash memory, it is necessary to contact a semiconductor layer and a metal electrode, both of which are included in a control gate, in order to reduce a gate delay time of a select gate transistor in a cell area and that of transistors in a peripheral circuit. Therefore, it is required to achieve good contact characteristics of a semiconductor-metal interface.

### BRIEF DESCRIPTION OF THE DRAWINGS

FIG. 1 is an example of an equivalent circuit diagram showing a memory cell array of a semiconductor device according to a first embodiment.

FIG. 2 is an example of a layout diagram of the memory cell array of the semiconductor device according to the first embodiment.

FIG. 3 is an example of a cross-sectional view of the memory cell array of the semiconductor device according to the first embodiment.

FIG. 4A is an example of a cross-sectional view of the memory cell array of the semiconductor device according to the first embodiment.

FIG. 4B is an example of a cross-sectional view of the memory cell array of the semiconductor device according to the first embodiment.

FIG. 5 is an example of a layout diagram of a peripheral circuit region of the semiconductor device according to the first embodiment.

FIG. 6 is an example of a cross-sectional view of the peripheral circuit region of the semiconductor device according to the first embodiment.

FIG. 7 is an example of a cross-sectional view of the peripheral circuit region of the semiconductor device according to the first embodiment.

FIG. 8 is an example of across-sectional view showing a manufacturing method of the peripheral circuit region of the semiconductor device according to the first embodiment.

FIG. 9 is an example of a cross-sectional view showing the manufacturing method of the peripheral circuit region of the semiconductor device according to the first embodiment.

FIG. 10 is an example of a cross-sectional view showing the manufacturing method of the peripheral circuit region of the semiconductor device according to the first embodiment.

FIG. 11 is an example of a cross-sectional view showing the manufacturing method of the peripheral circuit region of the semiconductor device according to the first embodiment.

FIG. 12 is an example of a cross-sectional view showing the manufacturing method of the peripheral circuit region of the semiconductor device according to the first embodiment.

FIG. 13 is an example of a view explaining the manufacturing method of the peripheral circuit region of the semiconductor device according to the first embodiment.

FIG. 14 is an example of a view explaining the manufacturing method of the peripheral circuit region of the semiconductor device according to the first embodiment.

FIG. 15 is an example of a cross-sectional view showing the manufacturing method of the peripheral circuit region of the semiconductor device according to the first embodiment.

FIG. 16 is an example of a view explaining the peripheral circuit region of the semiconductor device according to the first embodiment.

FIG. 17 is an example of a view explaining the peripheral circuit region of the semiconductor device according to the first embodiment.

FIG. 18 is an example of a view explaining the peripheral circuit region of the semiconductor device according to the first embodiment.

FIG. 19 is an example of a view explaining the peripheral circuit region of the semiconductor device according to the first embodiment.

FIG. 20 is an example of a view explaining the peripheral circuit region of the semiconductor device according to the first embodiment.

FIG. 21A is an example of a cross-sectional view of a memory cell array of a semiconductor device according to a second embodiment.

FIG. 21B is an example of a cross-sectional view of a memory cell array of a semiconductor device according to a second embodiment.

FIG. 21C is an example of a cross-sectional view of a memory cell array of a semiconductor device according to a second embodiment.

FIG. 21D is an example of a cross-sectional view of a memory cell array of a semiconductor device according to a second embodiment.

FIG. 22 is an example of a cross-sectional view showing a manufacturing method of the memory cell array of the semiconductor device according to the second embodiment.

FIG. 23 is an example of a cross-sectional view showing the manufacturing method of the memory cell array of the semiconductor device according to the second embodiment.

### DETAILED DESCRIPTION

A semiconductor device according to an embodiment comprises: a gate insulating film formed on a semiconductor substrate; a semiconductor layer formed on the gate insulating film; and a first metal layer formed to be electrically connected to the semiconductor layer. 1×10¹⁹ atoms/cm³ or more of a Group VI element exists in an interface of the semiconductor layer and the first metal layer.

A semiconductor device according to embodiments will be described below with reference to the drawings. In the embodiments, the semiconductor device and a manufacturing method thereof will be described as a nonvolatile semiconductor memory device, that is, a NAND type flash memory, and a manufacturing method thereof, but the embodiments are not limited to the nonvolatile semiconductor memory device and the manufacturing method thereof. Note that in descriptions of the drawings in the embodiments below, places having an identical configuration are assigned with identical reference symbols, and description of those places is omitted. Moreover, the drawings are schematic and a relationship between thicknesses of each of films and dimensions of plane surfaces, ratios of thicknesses of each of layers, and so on, differ from those of the actual semiconductor device.

### First Embodiment

### Configuration of Semiconductor Device according to First Embodiment

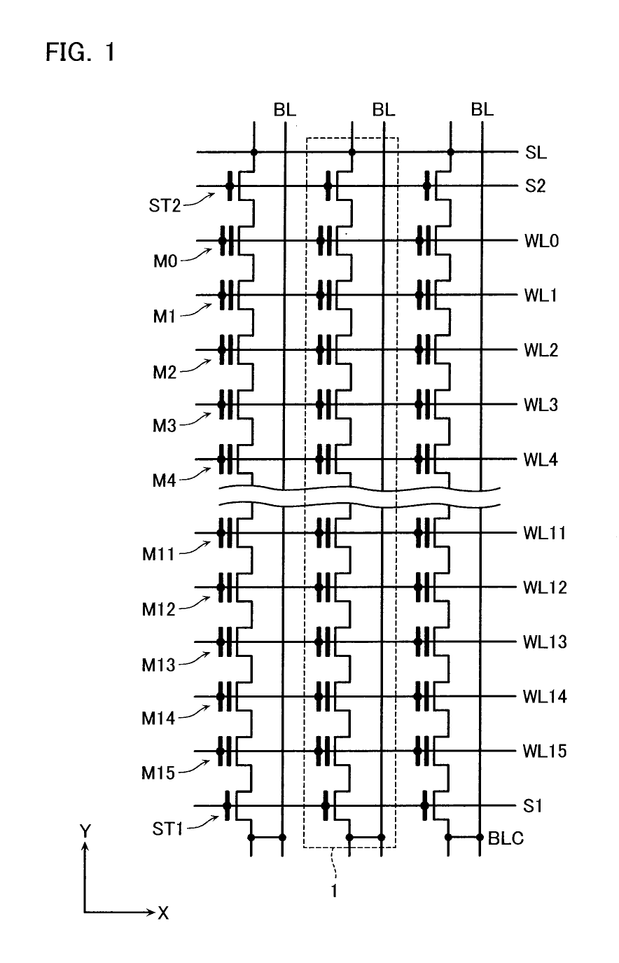

A configuration of a semiconductor device according to a first embodiment will be described below with reference to FIGS. 1 to 6. First, a configuration of a NAND type flash memory of the present embodiment will be described.

FIG. 1 is an equivalent circuit diagram showing part of a memory cell array formed in a memory cell region of the NAND type flash memory. A NAND cell unit 1 of the NAND type flash memory is configured from two select gate transistors ST1 and ST2, and a plurality of memory cell transistors Mn (n is, for example, an integer from 0 to 15, same applies below) connected in series between the select gate transistors ST1 and ST2. In the NAND cell unit 1, the plurality of memory cell transistors Mn are formed to share source/drain regions with adjacent memory cell transistors. The memory cell array is configured by having the NAND cell units 1 provided in a matrix.

Control gate electrodes of the memory cell transistors Mn arranged in an X direction (corresponding to word line direction and gate width direction) in FIG. 1 are commonly connected by word lines WLn, respectively. In addition, gate electrodes of the select gate transistors ST1 arranged in the X direction in FIG. 1 are commonly connected by a select gate line Si, and gate electrodes of the select gate transistors ST2 arranged in the X direction in FIG. 1 are commonly connected by a select gate line S2. Connected to a drain region of the select gate transistor ST1 is a bit line contact BLC. This bit line contact BLC is connected to a bit line BL that extends in a Y direction (corresponding to bit line direction and gate length direction) perpendicular to the X direction in FIG. 1. In addition, the select gate transistor ST2 is connected, via a source region, to a source line SL that extends in the X direction in FIG. 1.

As will be described later, the memory cell transistor Mn includes an N type source/drain region formed in a P type well of a silicon substrate and has a stacked gate structure (gate electrode MGn) including a floating gate electrode acting as a charge accumulation layer and a control gate electrode. The NAND type flash memory changes a threshold voltage of the memory cell transistor Mn by changing an amount of charge held in this floating gate electrode in a write operation and an erase operation, and thereby stores one bit or multiple bits of data. In the NAND type flash memory, a group of a plurality of NAND cell units 1 sharing a word line configures a block. Erase of data in the NAND type flash memory is executed in a unit of this block.

### Configuration of Memory Cell Array

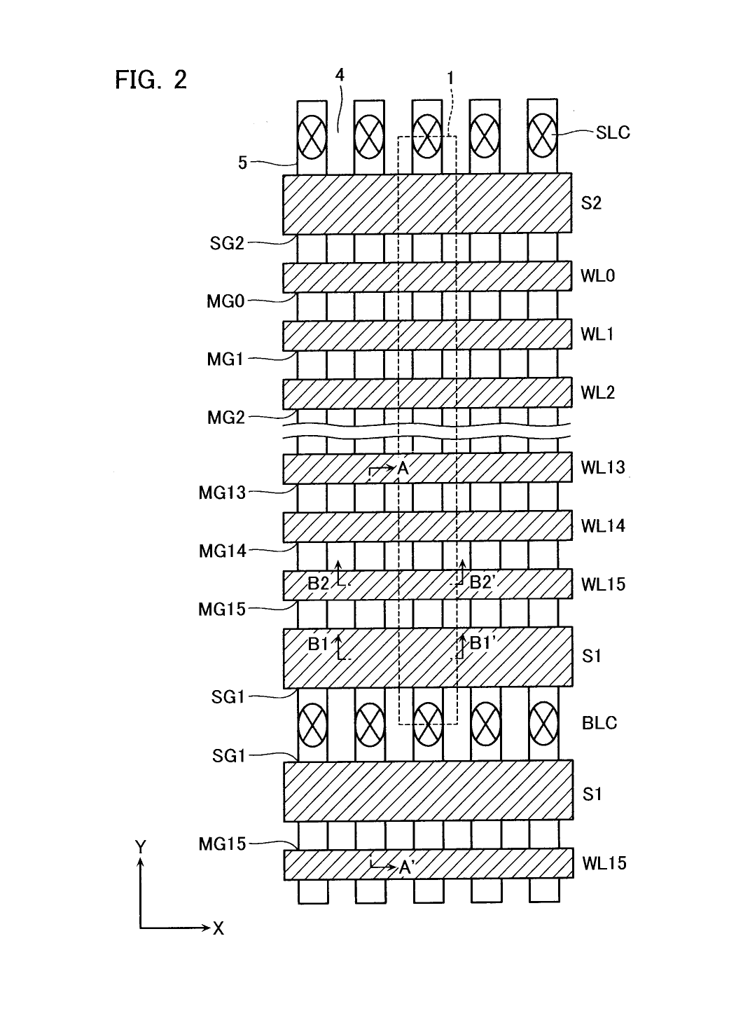

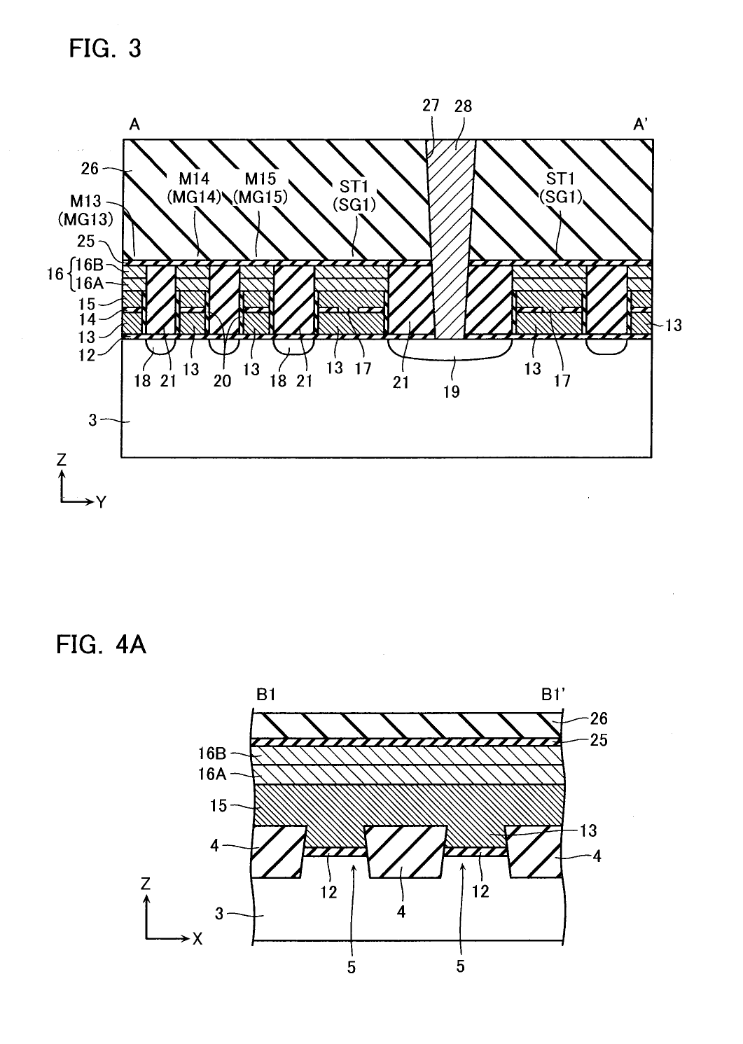

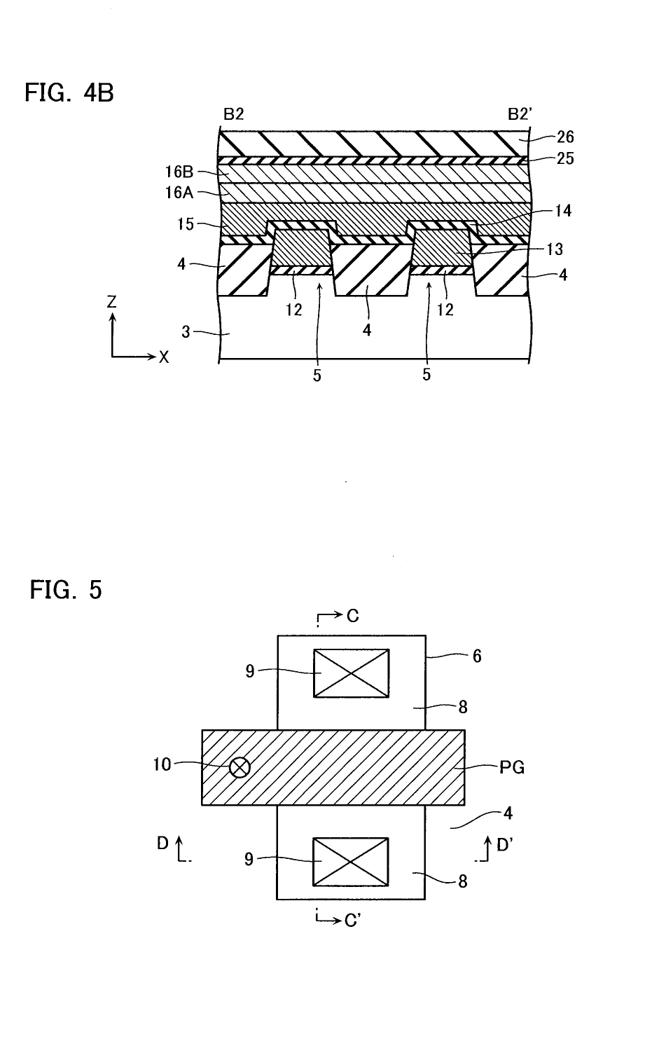

FIG. 2 is a layout diagram of part of the memory cell array formed in the memory cell region of the NAND type flash memory. FIG. 3 is a cross-sectional view taken along the line A-A′ shown in FIG. 2. FIG. 3 is a cross-sectional view of part of the memory cell array of the NAND type flash memory, with a part of a gate electrode SG1 of the select gate transistor ST1 being in a center position thereof. FIG. 4A is a cross-sectional view taken along the line B1-B1′ shown in FIG. 2. FIG. 4A is a cross-sectional view of part of the memory cell array of the NAND type flash memory, with a part of a gate electrode SG1 of the select gate transistor ST1 being in a center position thereof. FIG. 4B is a cross-sectional taken along the line B2-B2′ shown in FIG. 2. FIG. 4B is a cross-sectional view of part of the memory cell array of the NAND type flash memory, with a part of a gate electrode MG15 of the memory cell transistor M15 being in a center position thereof.

FIGS. 2 to 4B illustrate configurations of the memory cell transistor Mn and the select gate transistors ST1 and ST2 in the memory cell array, and omit illustration of the bit line BL and the source line SL.

As shown in FIGS. 4A and 4B, an element isolation region 4 of STI (Shallow Trench Isolation) structure is formed in a p type silicon substrate 3 doped with, for example, 1×10¹⁵ atoms/cm³ of boron (B) atoms. The element isolation region 4 electrically isolates the silicon substrate 3 into a plurality of element regions 5.

A plurality of the element isolation regions 4 are formed with a certain spacing in the X direction and having the Y direction shown in FIG. 2 as a longer direction. Moreover, the element regions 5 are formed isolated in the X direction and having the Y direction shown in FIG. as a longer direction. Disposed in each of the plurality of element regions 5 are the plurality of memory cell transistors Mn. The NAND cell unit 1 is configured by the plurality of memory cell transistors Mn aligned in the Y direction and the select gate transistors ST1 and ST2 provided at both ends of these plurality of memory cell transistors Mn.

As shown in FIG. 2, the word lines WLn are formed with a certain spacing in the Y direction and having the X direction shown in FIG. 2 as a longer direction, to be orthogonal to the element region 5. The word line WLn is commonly connected to a plurality of the memory cell transistors Mn aligned in the X direction. The word line WLn forms the gate electrode MGn (control gate electrode) of the memory cell transistor Mn on the element region 5 where the element region 5 intersects the word line WLn.

In addition, the select gate line S1 connected to the select gate transistor ST1 is formed having the X direction shown in FIG. 2 as a longer direction. The select gate line S1 forms the gate electrode SG1 of the select gate transistor ST1 on the element region 5 where the element region 5 intersects the select gate line S1. The bit line contacts BLC are respectively formed in the element region 5 between two adjacent select gate lines S1. This bit line contact BLC is connected to the bit line BL not illustrated that has the Y direction shown in FIG. 2 as a longer direction.

Moreover, the select gate line S2 connected to the select gate transistor ST2 is formed having the X direction shown in FIG. 2 as a longer direction. The select gate line S2 forms the gate electrode SG2 of the select gate transistor ST2 on the element region 5 where the element region 5 intersects the select gate line S2. A source line contact SLC is formed in the element region 5 next to the select gate line S2 in the Y direction. Respective source line contacts SLC are connected to the source line SL not illustrated that has the X direction shown in FIG. 2 as a longer direction.

As shown in FIGS. 3, 4A, and 4B, a tunnel insulating film 12 of film thickness 4 nm to 16 nm acting as a gate insulating film is formed on the silicon substrate 3. The gate electrodes MGn (n is, for example, an integer from 0 to 15, same applies below) of the memory cell transistors Mn (n is, for example, an integer from 0 to 15, same applies below) and the gate electrode SG1 of the select gate transistor ST1 are formed via this tunnel insulating film 12. These gate electrodes MGn and SG1 have a configuration in which there are sequentially stacked a floating gate electrode-dedicated polysilicon film 13, an inter-electrode insulating film 14, a control gate electrode-dedicated polysilicon film 15, and a metal layer 16. Employed in the inter-electrode insulating film 14 are the likes of an ONO structure configured from silicon oxide film-silicon nitride film-silicon oxide film, or a NONON structure in which the ONO structure is further sandwiched by silicon nitride films. Furthermore, it may also include a high-permittivity material, for example, aluminum oxide (Al₂O₃), hafnium silicate (HfSiO), or the like, in order to increase a coupling ratio of the memory cell transistor Mn. The metal layer 16 is formed by a stacked structure of a first metal layer 16A and a second metal layer 16B. The first metal layer 16A is formed by, for example, tungsten nitride (WN), and the second metal layer 16B is formed by, for example, tungsten (W). The first metal layer 16A and the second metal layer 16B may employ an identical metal material. In addition to tungsten (W), metal materials such as copper (Cu), titanium nitride (TiN), aluminum (Al), or AlSiCu may be employed as the metal material used in the metal layer 16.

Moreover, as shown in FIG. 3, an impurity diffusion region 18 that is to be the source/drain region is formed in a surface layer (surface) of the silicon substrate 3 between the gate electrodes MGm and MGm+1 (m is, for example, an integer from 0 to 14, same applies below) and between the gate electrodes MG15 and SG1. The impurity diffusion region 18 is formed such that source/drain regions are shared by adjacent memory cell transistors Mn. An impurity diffusion region 19 of high concentration is formed in the surface layer of the silicon substrate 3 between the gate electrodes SG1 and SG1. Note that the source/drain region between the gate electrodes SG1 and SG1 may adopt not only the high concentration impurity diffusion region 19, but also an LDD (Lightly Doped Drain) structure including a shallow impurity diffusion region of low concentration.

As shown in FIG. 3, a silicon oxide film 20 is formed on side surfaces of the gate electrode MGn and the gate electrode SG1 by, for example, a RTP (Rapid Thermal Processor) method. An inter-layer insulating film 21 of the likes of a BPSG (Boron Phosphorus Silicate Glass) film or silicon oxide film is formed so as to fill the gate electrode MGn of the memory cell transistor Mn and the gate electrode SG1 of the select gate transistor ST1.

As shown in FIG. 3, an opening 17 for electrical connecting between the polysilicon film 13 and the polysilicon film 15 is formed in the inter-electrode insulating film 14 of the gate electrode SG1 of the select gate transistor ST1, and the polysilicon film 15 is filled into this opening 17. The polysilicon film 13 and the polysilicon film 15 are connected by this opening 17. In the select gate transistor ST1, the polysilicon film 13, the polysilicon film 15, and the metal layer 16 configure one control gate electrode. Similarly also in the select gate transistor ST2, the opening 17 is formed in the inter-electrode insulating film 14, and the polysilicon film 13, the polysilicon film 15, and the metal layer 16 configure one control gate electrode, although illustration of this is omitted.

As shown in FIGS. 3, 4A, and 4B, a silicon nitride film 25 is formed on upper surfaces of the gate electrodes MGn and SG1 and on an upper surface of the inter-layer insulating film 21, so as to cover these. A TEOS film is formed on the silicon nitride film 25 and is planarized.

As shown in FIG. 3, a contact hole 27 reaching from an upper surface of the TEOS film 26 to a surface of the impurity diffusion region 19 of the silicon substrate 3, is formed. This contact hole 27 is formed so as to penetrate the TEOS film 26, the silicon nitride film 25, and the inter-layer insulating film 21 and expose the surface of the silicon substrate 3. A contact plug 28 having a conductor formed embedded therein is formed inside the contact hole 27, and is electrically connected to the silicon substrate 3. This contact plug 28 configures the bit line contact BLC shown in FIG. 2.

The bit line BL having the Y direction as a longer direction, the source line SL having the X direction as a longer direction, and so on, are formed above the TEOS film 26, although illustration of this is omitted in FIGS. 3, 4A, and 4B.

### Configuration of Peripheral Circuit Region

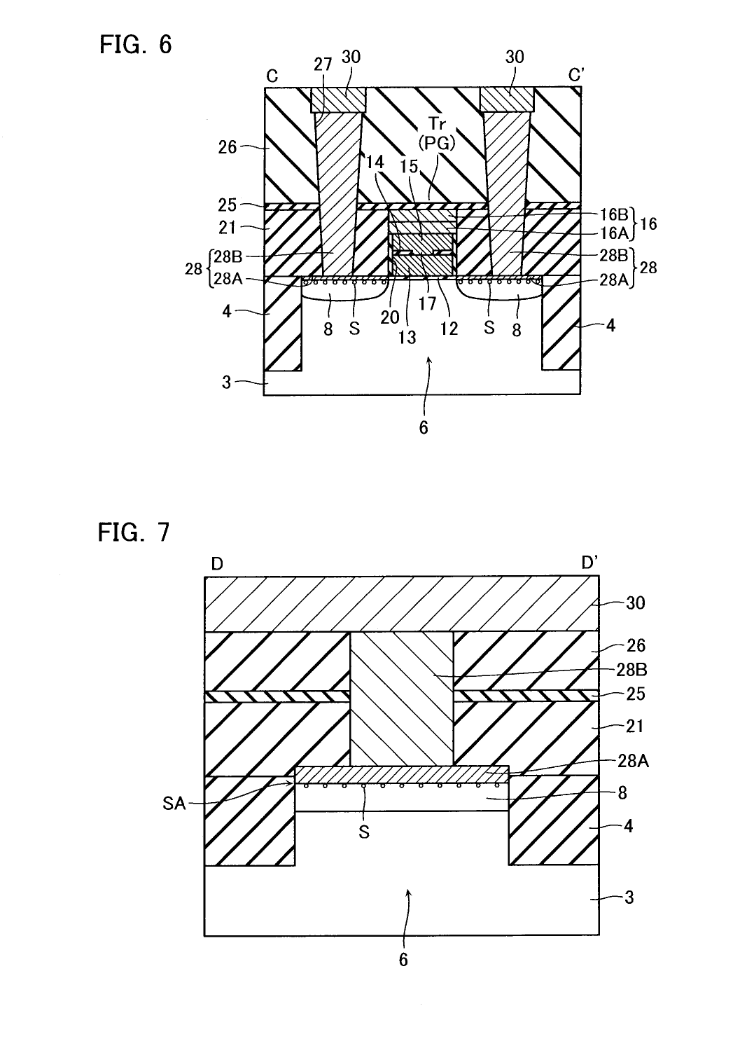

FIG. 5 is a layout diagram of a transistor formed in a peripheral circuit region of the NAND type flash memory. FIG. 6 is a cross-sectional view taken along the line C-C′ shown in FIG. 5. FIG. 6 is a cross-sectional view of a transistor Tr formed in the peripheral circuit region of the NAND type flash memory. FIG. 7 is a cross-sectional view taken along the line D-D′ shown in FIG. 5. FIG. 7 is a cross-sectional view of the transistor Tr formed in the peripheral circuit region, with the contact plug 28 being in the center position.

The transistor Tr of the peripheral circuit region shown in FIGS. 5 to 7 that is formed by similar films to those of the select gate transistor ST1 of the memory cell array shown in FIGS. 2 to 4B is shown by identical reference symbols to those of FIGS. 2 to 4B. Note that in FIG. 5, illustration of a wiring line layer 30 which will be described later, is omitted.

As shown in FIGS. 6 and 7, an element isolation region 4 of STI (Shallow Trench Isolation) structure is formed in the silicon substrate 3. The element isolation region 4 isolates the silicon substrate 3 into a plurality of rectangular element regions 6. The transistor Tr is formed in each of these plurality of element regions 6.

As shown in FIGS. 5 and 6, the transistor Tr formed in the peripheral circuit region is provided on the element region 6 left in a rectangular shape in the silicon substrate 3. The element isolation region 4 is formed surrounding this element region 6. A gate electrode PG is formed in the element region 6 so as to traverse the element region 6, and a source/drain region 8 formed by diffusing an impurity is provided on both sides of the gate electrode PG. Contact plugs 9 and 10 are respectively formed in the source/drain region 8 and the gate electrode PG. The source/drain region 8 is an impurity diffusion region doped with, for example, about 1×10¹⁹ to 1×10²⁰ atoms/cm³ of phosphorus (P) atoms. Besides phosphorus (P), the likes of arsenic (As) or antimony (Sb), for example, may also be employed as the atoms for forming the source/drain region 8.

As shown in FIG. 6, a gate insulating film 12 is formed on the silicon substrate 3. The gate electrode PG of the transistor Tr is formed via this gate insulating film 12. The gate electrode PG has a configuration in which a polysilicon film 13, an inter-electrode insulating film 14, a polysilicon film 15, and a metal layer 16 are sequentially stacked.

Employed in the inter-electrode insulating film 14, similarly to in the inter-electrode insulating film 14 employed in the memory cell array, are the likes of an ONO structure configured from silicon oxide film-silicon nitride film-silicon oxide film, or a NONON structure in which the ONO structure is further sandwiched by silicon nitride films. The metal layer 16 is formed by a stacked structure of a first metal layer 16A and a second metal layer 16B. The first metal layer 16A is formed by, for example, tungsten nitride (WN), and the second metal layer 16B is formed by, for example, tungsten (W). The first metal layer 16A and the second metal layer 16B may employ an identical metal material. In addition to tungsten (W), metal materials such as copper (Cu), titanium nitride (TiN), aluminum (Al), or AlSiCu may be employed as the metal material used in the metal layer 16.

As shown in FIG. 6, an opening 17 for electrical connecting between the polysilicon film 13 and the polysilicon film 15 is formed in the inter-electrode insulating film 14 of the gate electrode PG of the transistor Tr, and the polysilicon film 15 is filled into this opening 17. The polysilicon film 13 and the polysilicon film 15 are connected by this opening 17. In the transistor Tr, the polysilicon film 13, the polysilicon film 15, and the metal layer 16 configure one gate electrode PG. An impurity diffusion region that is to be the previously mentioned source/drain region 8 is formed in a surface layer (surface) of the silicon substrate 3 on both sides of the gate electrode PG.

A silicon oxide film 20 is formed on a side surface of the gate electrode PG by, for example, a RTP method. An inter-layer insulating film 21 of the likes of a BPSG film or silicon oxide film is formed so as to fill the transistor Tr. A silicon nitride film 25 is formed on an upper surface of the gate electrode PG and on an upper surface of the inter-layer insulating film 21, so as to cover these. A TEOS film 26 is formed on the silicon nitride film 25 and is planarized.

As shown in FIGS. 6 and 7, a contact hole 27 reaching from an upper surface of the TEOS film 26 to the surface of the silicon substrate 3 is formed in the source/drain region 8. This contact hole 27 is formed so as to penetrate the TEOS film 26, the silicon nitride film 25, and the inter-layer insulating film 21 and expose the surface of the silicon substrate 3. A contact plug 28 having a conductor formed embedded therein is formed inside the contact hole 27, and is electrically connected to the silicon substrate 3. This contact plug 28 configures the contact plug 9 shown in FIG. 5.

The contact plug 28 is formed by a stacked structure of a first contact plug layer 28A and a second contact plug layer 28B. The first contact plug layer 28A is formed by, for example, tungsten nitride (WN), and the second contact plug layer 28B is formed by, for example, tungsten (W). The first contact plug layer 28A and the second contact plug layer 28B may employ an identical metal material. In addition to tungsten (W), metal materials such as copper (Cu), titanium nitride (TiN), aluminum (Al), or AlSiCu may be employed as the metal material used in the contact plug 28. The contact plug layer 28A is formed extending over substantially an entire region of an upper surface of the source/drain region 8.

As shown in FIGS. 6 and 7, the wiring line layer 30 formed by, for example, copper (Cu) is provided on an upper surface of the contact plug 28. The transistor Tr and other elements, and so on, are electrically connected by this wiring line layer 30. The contact plug layer 28B and the wiring line layer 30 may be formed in an integrated structure by an identical material.

The contact plug layer 28A may include between itself and a part or the whole of the source/drain region 8 an insulating film of a thickness of 2 nm or less.

### Configuration of Junction

In the peripheral circuit region of the present embodiment configured in this way, a surface portion of the source/drain region 8 of the silicon substrate 3 contains 1×10¹⁹ atoms/cm³ or more of sulfur (S) atoms in a part or the whole of the region. That is, the transistor Tr contains 1×10¹⁹ atoms/cm³ or more of sulfur (S) atoms on a side of the silicon substrate 3 of a junction interface SA between the source/drain region 8 of the silicon substrate 3 and the contact plug layer 28A. As will be described in detail later, in the junction interface SA between the source/drain region 8 of the silicon substrate 3 and the contact plug layer 28A of the transistor Tr, sulfur (S) atoms exist in pairs at adjacent lattice positions of a lattice atomic structure.

### Manufacturing Method of Semiconductor Device

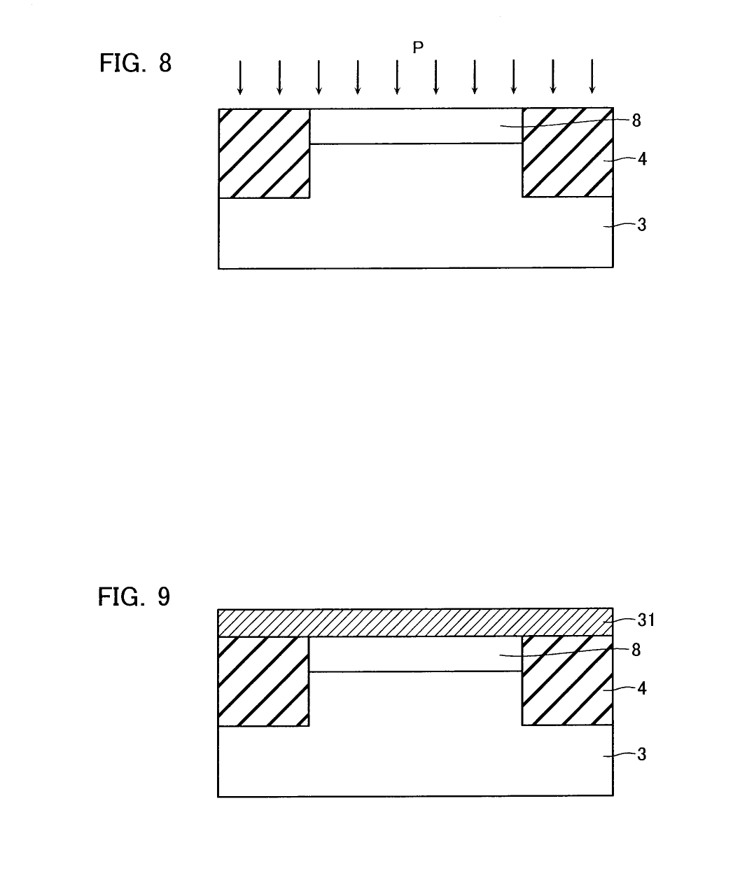

Next, a manufacturing method of the semiconductor device of the present embodiment will be described with reference to FIGS. 8 to 15. The manufacturing method of the semiconductor device of the present embodiment will be described as a manufacturing method relating to a junction portion between the source/drain region 8 of the silicon substrate 3 and the contact plug layer 28A of the transistor Tr of the peripheral circuit region.

FIGS. 8 to 12, and 15 are cross-sectional views showing the manufacturing method of the semiconductor device of the present embodiment.

First, as shown in FIG. 8, the element isolation region 4 of STI (Shallow Trench Isolation) structure configured from a silicon oxide film is formed in the p type silicon substrate 3 of plane orientation (100) plane doped with, for example, about 1×10¹⁵ atoms/cm³ of boron (B) atoms. Then, the source/drain region 8 is formed in the silicon substrate by ion implantation of an impurity such as phosphorus (P).

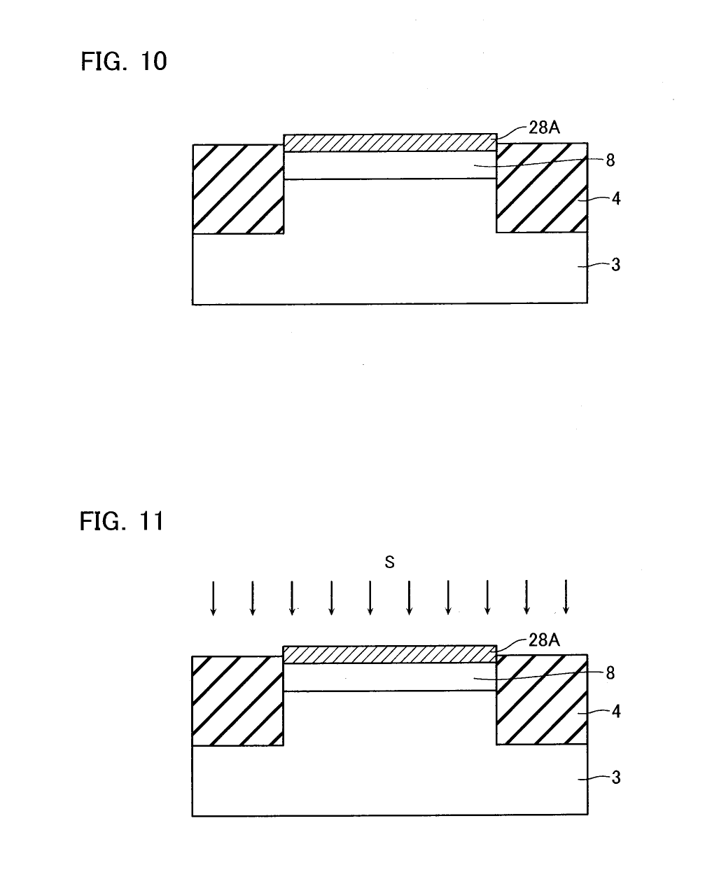

Next, as shown in FIG. 9, a metal film 31 is formed by depositing tungsten nitride (WN) of a thickness of about 8 nm on the silicon substrate 3, by, for example, a sputtering method. The metal film 31 is to be the contact plug layer 28A after subsequent processing steps are passed through. Then, as shown in FIG. 10, excess metal film 31 is removed by a chemical to form the contact plug layer 28A.

Next, as shown in FIG. 11, sulfur (S) is implanted into the contact plug layer 28 by, for example, ion implantation. Now, when performing the ion implantation of sulfur (S), an implantation acceleration voltage is set such that a range (projected range, Rp) of the ion implantation is about a film thickness of the contact plug layer 28A. That is, the implantation acceleration voltage is set such that a concentration peak of sulfur (S) atoms immediately after the ion implantation falls within the contact plug layer 28A.

For example, in the case that the film thickness of the contact plug layer 28A is 8 nm, if the implantation acceleration voltage of sulfur (S) is set to 10 keV, then the projected range Rp is 6 nm and the projected range Rp can be set to about the film thickness of the contact plug layer 28A. Contrary to the case where sulfur (S) is implanted into silicon, in the present embodiment, sulfur (S) is implanted into the contact plug layer 28A, hence the contact plug layer 28A functions as a stopper layer of sulfur (S). Therefore, it is possible to suppress diffusion of sulfur (S) to a deep region of the silicon substrate 3, and a shallow and steep sulfur (S) profile can be achieved.

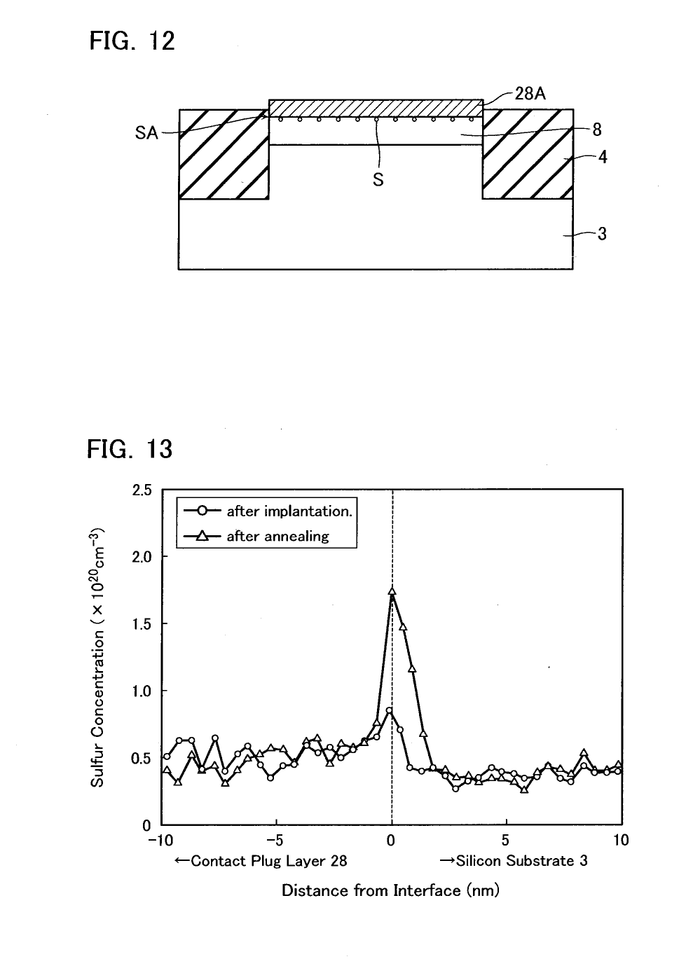

Next, as shown in FIG. 12, annealing for, for example, about one minute at 750° C. is performed in an inert gas atmosphere as a heat treatment, by, for example, RTA (Rapid Thermal Annealing). As a result of this heat treatment, damage such as a defect occurring inside the silicon substrate 3 or inside the contact plug layer 28A due to the ion implantation of sulfur (S) is repaired and implanted sulfur (S) is redisposed to an energetically stable position.

Sulfur (S) atoms existing in silicon charge positively due to migration of electronic charge and are attracted by tungsten nitride (WN) due to a mirror effect with the contact plug layer 28A, thereby approaching the contact plug layer 28A by the heat treatment. In addition, sulfur (S) atoms are more stable in silicon (Si) than in tungsten nitride (WN), hence sulfur (S) atoms existing in tungsten nitride (WN) diffuse to a silicon (Si) side due to the heat treatment. In this way, sulfur (S) segregates to a vicinity of the interface between the contact plug layer 28A and the silicon substrate 3 due to the heat treatment. As a result, a steep segregation peak of sulfur (S) is obtained.

FIG. 13 is a graph showing a sulfur (S) profile before and after the heat treatment. The vertical axis of FIG. 13 indicates sulfur (S) concentration, and the horizontal axis of FIG. 13 indicates distance from the junction interface SA between the contact plug layer 28A and the silicon substrate 3. As shown in FIG. 13, before the heat treatment, a concentration of sulfur (S) atoms in a vicinity of the junction interface between the contact plug layer 28A and the silicon substrate 3 is at most about 0.8×10²⁰ atoms/cm³. Due to the above-described heat treatment, sulfur (S) atoms segregate to the vicinity of the junction interface between the contact plug layer 28A and the silicon substrate 3. After the heat treatment, the concentration of sulfur (S) atoms in the vicinity of the junction interface between the contact plug layer 28A and the silicon substrate 3 is about 1.8×10²⁰ atoms/cm³. This heat treatment makes it possible to form an interface SA containing 1×10¹⁹ atoms/cm³ or more of sulfur (S) between the contact plug layer 28A and the silicon substrate 3.

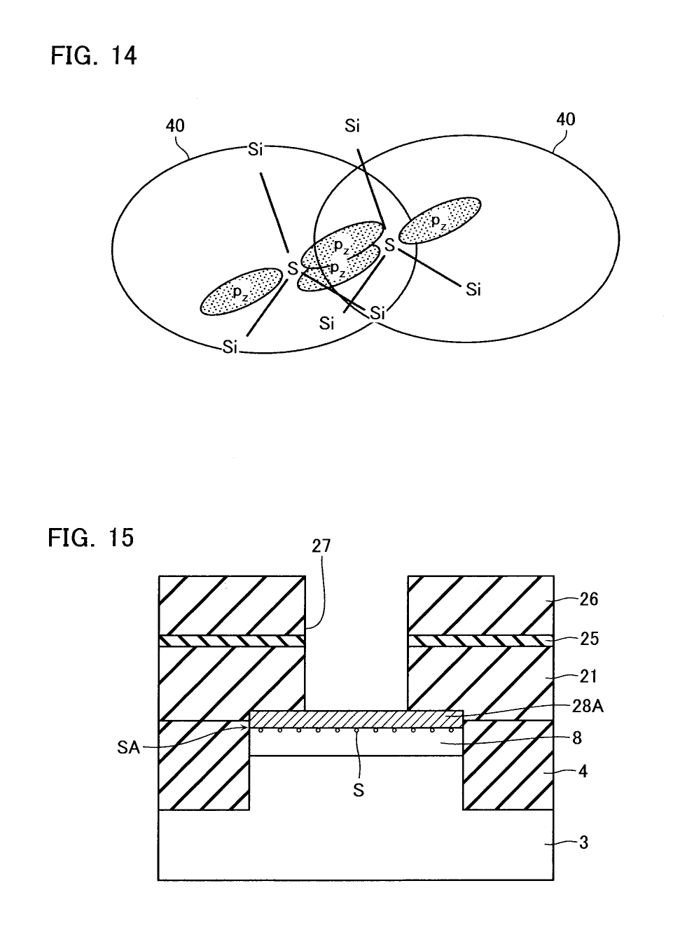

As shown in FIG. 14, at this time, in the junction interface SA between the contact plug layer 28A and the silicon substrate 3, sulfur (S) atoms are disposed in the most energetically stable structure of a pair in the lattice atomic structure. Each of the sulfur (S) atoms orbit-couples with three nearest-neighbor Si atoms. Electrons in a Pz orbit perpendicular to this coupled orbit formation plane undergo energetic degeneration of both up-spin and down-spin to be coupled to a valence band of a peripheral silicon atom. These surplus electrons become donors where a wave function 40 extends with the sulfur (S) atom being in the center thereof.

The junction interface SA between the contact plug layer 28A and the silicon substrate 3 is preferably formed to contain 1×10¹⁹ atoms/cm³ or more of sulfur (S) by the ion implantation of sulfur (S) and the heat treatment.

This is because the junction interface SA between the contact plug layer 28A and the silicon substrate 3 containing 1×10¹⁹ atoms/cm³ or more of sulfur (S) enables formation of a contact structure having excellent ohmic characteristics.

Next, as shown in FIG. 15, the inter-layer insulating film 21 of a silicon oxide is deposited on the silicon substrate 3 by, for example, a CVD (Chemical Vapor Deposition) method. Then, the silicon nitride film 25 and the TEOS film 26 are formed, and opening of the contact hole 27 is performed by an etching technology such as a publicly-known lithography method and reactive ion etching (also referred to below as RIE).

Then, the contact plug layer 28B of tungsten (W) is formed by, for example, the CVD method. Then, the wiring line layer 30 of, for example, Cu is formed on the contact plug layer 28B, thereby manufacturing the semiconductor device of the contact structure shown in FIGS. 6 and 7.

The above manufacturing method described the case of employing tungsten nitride (WN) in the contact plug layer 28A, but the contact plug layer 28A may be a metal nitride including as its main component any of tungsten (W), tantalum (Ta), molybdenum (Mo), niobium (Nb), iridium (Ir), ruthenium (Ru), and hafnium (Hf). Moreover, the metal material employed in the contact plug 28 may be a metal not including nitrogen provided it is a high melting point metal whose melting point is 2000° C. or more.

In addition, it is also possible for an insulating layer of a thickness of 2 nm or less to be formed between the silicon substrate 3 and the contact plug layer 28A by a natural oxide film being formed in the manufacturing steps.

### Advantages

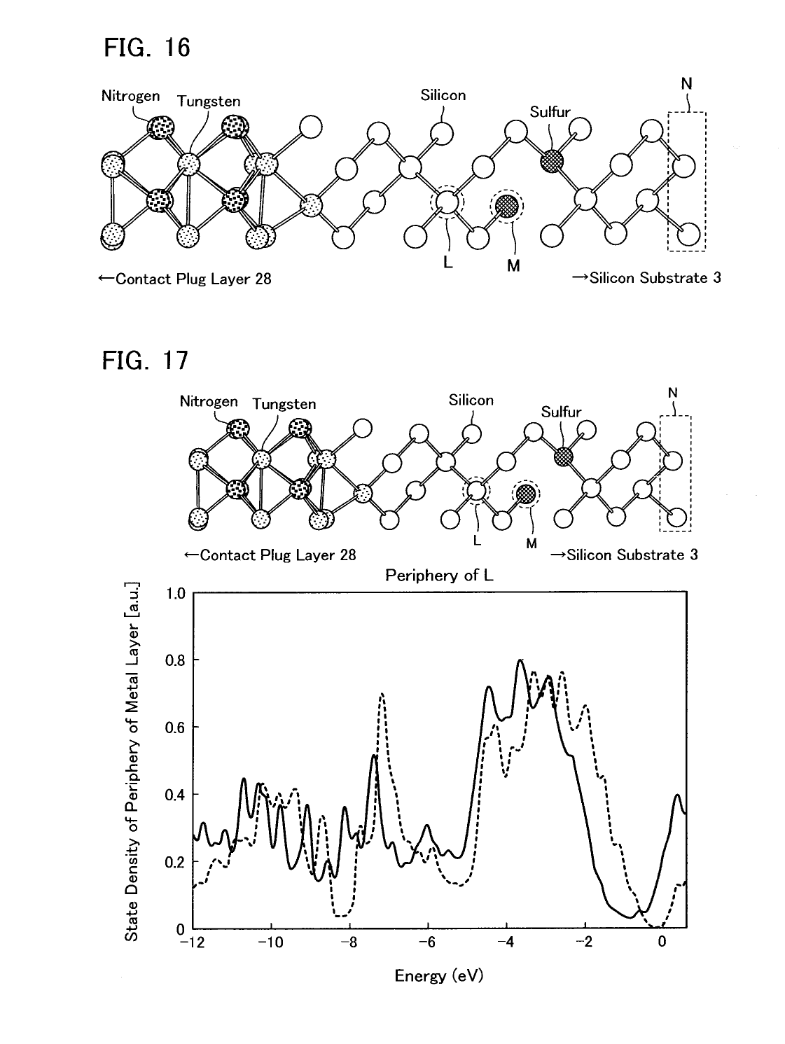

FIG. 16 is a view showing atomic structure of the junction portion between the silicon substrate 3 and the contact plug layer 28 of the semiconductor device according to the present embodiment. Due to the ion implantation of sulfur (S) and the heat treatment, sulfur atoms exist in pairs in the junction interface SA between the silicon substrate 3 and the contact plug layer 28A.

FIGS. 17 to 19 are graphs respectively showing state density of a closely adjacent portion L to the contact plug layer 28, state density of a closely adjacent portion M to the sulfur atom (S), and state density of a closely adjacent portion N to the silicon atom, shown in FIG. 16. In FIGS. 17 to 19, state density in the case where sulfur atoms are implanted is shown by a solid line, and state density in the case where sulfur atoms are not implanted is shown by a broken line.

As shown by the broken lines in FIGS. 17 to 19, in the case where sulfur atoms are not implanted, state density does not have a value at places where the energy level is 0 eV (Fermi level) and this indicates a Fermi level exists on a band gap. Therefore, in the state where sulfur is not implanted, silicon atoms of the silicon substrate 3 show properties of a semiconductor.

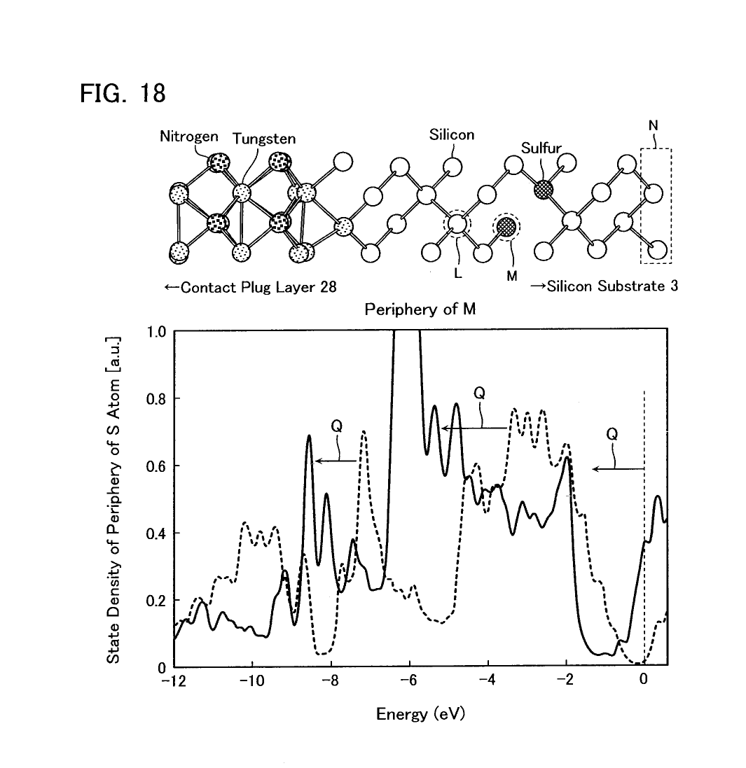

Now, when sulfur atoms are implanted in the silicon substrate 3, the energy level changes in a periphery of the sulfur atoms due to electrons in the Pz orbit in the vicinity of the paired sulfur atoms. As shown by the solid line in FIG. 18, the energy level lowers by approximately 2 eV in the periphery of the sulfur atoms compared to the case where sulfur has not been implanted (refer to arrows Q).

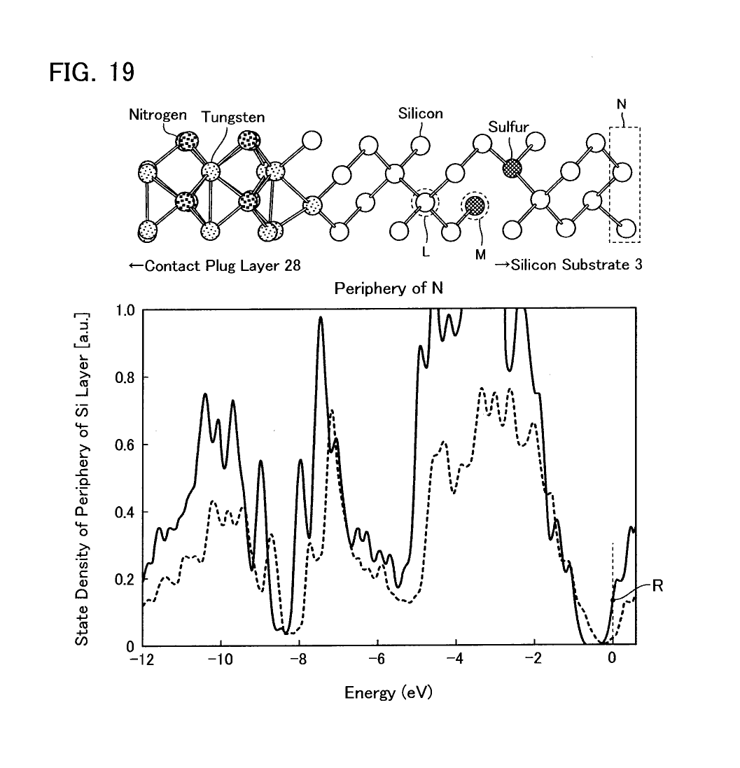

A wave function of the electrons in the Pz orbit in the periphery of the paired sulfur atoms extends to the closely adjacent portion N to the silicon atoms of the silicon substrate 3. Hence, as shown in FIG. 19, the energy level lowers also in the periphery of the silicon atoms due to the electrons in the periphery of the sulfur atoms. As shown in FIG. 19, due to state density taking a finite value (point R) when the energy level is 0 eV, electrons exist in the periphery of the silicon atoms and metallic properties are shown.

When a high concentration of sulfur exists in the interface SA between the metal layer (contact plug layer 28A) and the semiconductor layer (silicon substrate 3) as in the present embodiment, the conductive band of the silicon substrate 3 is pinned to the Fermi level of the contact plug layer 28A by sulfur, whereby electronic Schottky barrier height is substantially zero. FIG. 20 is a graph showing Schottky barrier height of the metal layer (contact plug layer 28A) and Schottky barrier height in the case where sulfur atoms have been implanted. Moreover, FIG. 20 shows also at the same time Schottky barrier height in the case where selenium (Se) which is an element of the same Group VI is implanted instead of sulfur. Siliciding is sometimes performed in manufacturing steps of the semi conductor device, and FIG. 20 respectively shows Schottky barrier height when ion implantation is performed before and after the siliciding step. As shown in FIG. 20, Schottky barrier height is found to lower regardless of whether sulfur (or selenium) implantation is performed either before or after the siliciding step.

Even when a semiconductor material employed in the semiconductor device is silicon, Schottky barrier height becomes substantially zero due to implanting sulfur atoms, and a lower barrier can be obtained than by employing any generally known metal. Moreover, interface resistance at the interface SA between the contact plug layer 28A and the silicon substrate 3 depends exponentially on Schottky barrier height. Hence, by implanting sulfur to reduce Schottky barrier height, interface resistance can be significantly reduced. As a result, the semiconductor device according to the present embodiment makes it possible to lower resistance of the contact structure between the contact plug layer 28A and the silicon substrate 3.

Moreover, during manufacture of the semiconductor device, even if a thin insulating film is formed directly below the contact plug layer 28A, provided a thickness of the thin insulating film is 2 nm or less, the electronic wave function passes through the thin insulating film to extend to a silicon substrate 3 side and the conductive band of the silicon substrate 3 is pinned to the Fermi level of the contact plug layer 28A, whereby electronic Schottky barrier height becomes substantially zero. In this case, it possible to lower resistance of the contact structure between the contact plug layer 28A and the silicon substrate 3.

### Second Embodiment

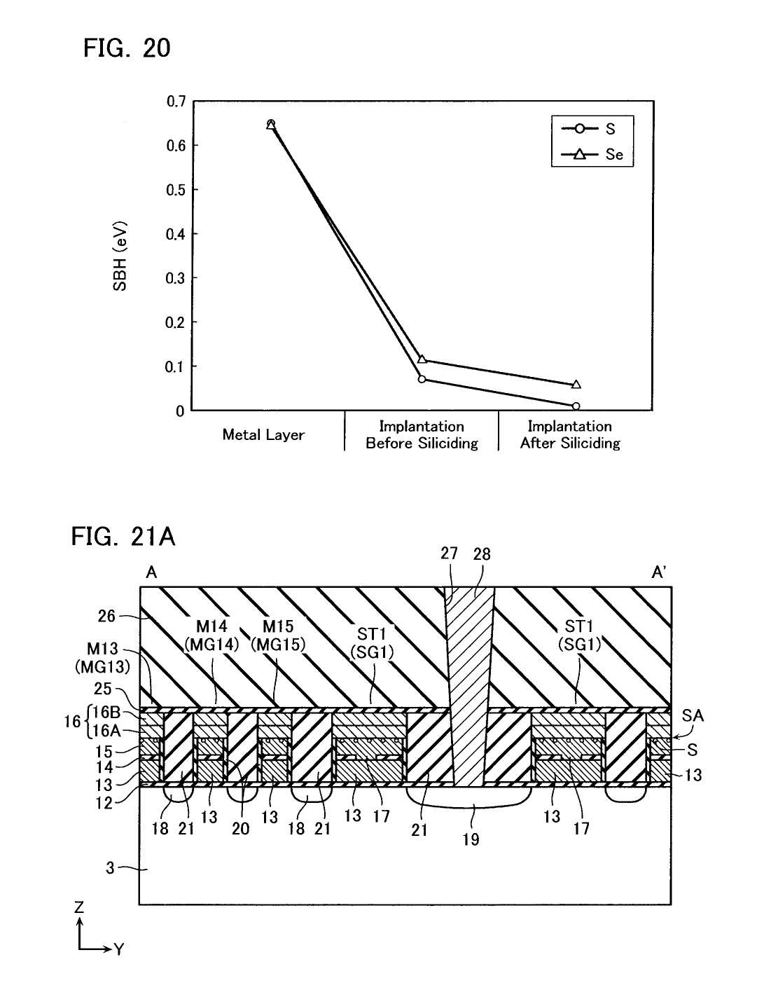

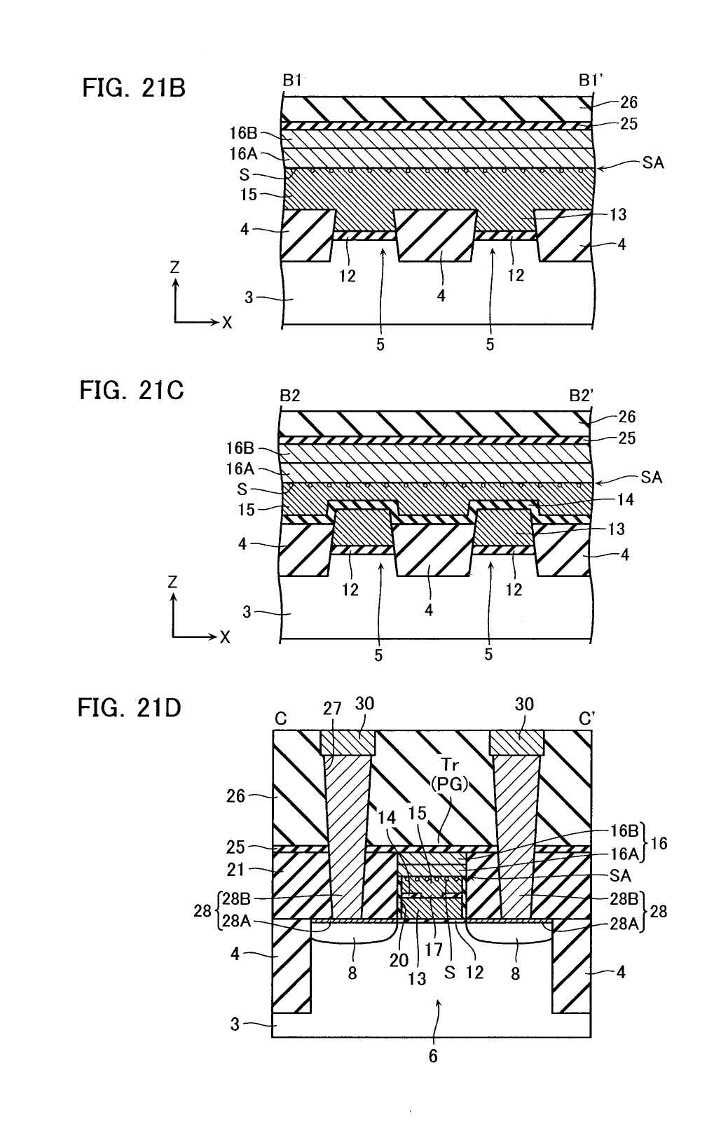

Next, a second embodiment of the present invention will be described with reference to FIG. 21A to FIG. 21C. An overall configuration of a semiconductor device of the second embodiment is similar to that of the first embodiment, and a detailed description thereof will be omitted. Moreover, places having a similar configuration to those in the first embodiment are assigned with identical reference symbols, and a duplicated description of such places will be omitted.

In the first embodiment, sulfur atoms were implanted into the interface between the contact plug 28 and the silicon substrate 3 of the transistor Tr of the peripheral circuit region. The semiconductor device of the present embodiment has sulfur atoms implanted into an interface between the polysilicon film 15 and the metal layer 16 in a transistor (for example, the select gate transistors ST1 and ST2 in the memory cell array or the transistors Tr in the peripheral circuit region). The semiconductor device and a manufacturing method thereof according to the present embodiment will be described below with reference to FIG. 21A to FIG. 21C.

### Configuration of Memory Cell Array and Peripheral Circuit

FIG. 21A is a cross-sectional view taken along the line A-A′ shown in FIG. 2, and is a cross-sectional view of a place corresponding to the cross-sectional view shown in FIG. 3. FIG. 21B is a cross-sectional view taken along the line B1-B1′ shown in FIG. 2, and is a cross-sectional view of a place corresponding to the cross-sectional view shown in FIG. 4A. FIG. 21C is a cross-sectional view taken along the line B2-B2′ shown in FIG. 2, and is a cross-sectional view of a place corresponding to the cross-sectional view shown in FIG. 4B. FIG. 21D is a cross-sectional view taken along the line C-C′ shown in FIG. 5, and is a cross-sectional view of a place corresponding to the cross-sectional view shown in FIG. 6. FIG. 21B is a cross-sectional view of part of the memory cell array of the NAND type flash memory with a part of a gate electrode SG1 of the select gate transistor ST1 being in a center position.

In the present embodiment, sulfur atoms are implanted into an interface SA between the polysilicon film 15 and the metal layer 16 of the select gate transistors ST1 and ST2 in the memory cell array. A surface portion of the polysilicon film 15 contains 1×10¹⁹ atoms/cm³ or more of sulfur (S) atoms in a part or the whole of the region. That is, the select gate transistors ST1 and ST2 are configured to contain 1×10¹⁹ atoms/cm³ or more of sulfur (S) atoms on a side of the polysilicon film 15 of the junction interface SA between the polysilicon film 15 and the metal layer 16. In the junction interface SA between the polysilicon film 15 and the metal layer 16 of the select gate transistors ST1 and ST2, sulfur (S) atoms are configured to exist in pairs at adjacent lattice positions of a lattice atomic structure.

Furthermore, in the peripheral circuit region of the present embodiment configured in this way, a surface portion of the polysilicon film region 15 contains 1×10¹⁹ atoms/cm³ or more of sulfur (S) atoms in a part or the whole of the region. That is, the transistor Tr contains 1×10¹⁹ atoms/cm³ or more of sulfur (S) atoms on a side of the silicon substrate 3 of a junction interface SA between the polysilicon film 15 and the metal layer 16. As described above, in the junction interface SA between the polysilicon film 15 and the metal layer 16, sulfur (S) atoms exist in pairs at adjacent lattice positions of a lattice atomic structure.

### Manufacturing Method of Semiconductor Device

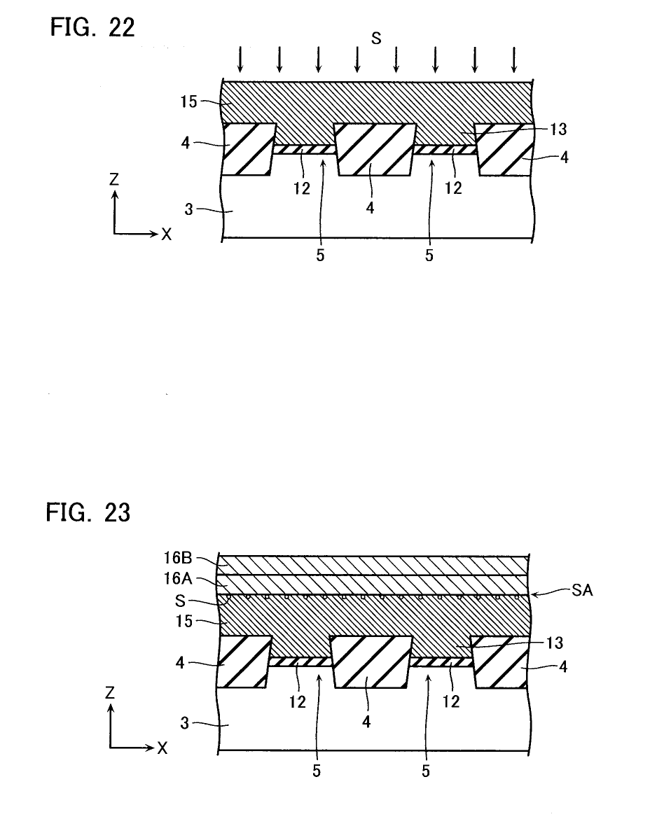

Next, the manufacturing method of the semiconductor device of the present embodiment will be described with reference to FIGS. 22 to 23. The manufacturing method of the semiconductor device of the present embodiment will be described as a manufacturing method relating to a junction portion between the polysilicon film 15 and the metal layer 16 of the select gate transistors ST1 and ST2 of the memory cell array.

FIGS. 22 to 23 are cross-sectional views showing the manufacturing method of the semiconductor device of the present embodiment.

As shown in FIG. 22, the element isolation region 4 is formed on the silicon substrate 3, and then the tunnel insulating film 12, the floating gate electrode-dedicated polysilicon film 13, the inter-electrode insulating film 14, and the control gate electrode-dedicated polysilicon film 15 are deposited on the silicon substrate 3. Then, sulfur (S) atoms are implanted into a surface of the polysilicon film 15.

An implanting method of sulfur atoms may employ ion implantation technology similarly to in the first embodiment. Moreover, the implanting method can also be achieved by exposing to plasma including sulfur in a plasma device such as a reactive ion etching device. For example, doping of sulfur from the surface of the polysilicon film 15 to the inside thereof can be achieved by attracting, by a bias associated with an ordinary reactive ion etching device, carbonyl sulfide (COS), carbon monoxide (CO), carbon sulfide (CS), sulfur oxide (SO), carbon (C), oxygen (O), sulfur (S), and their radicals and ionized products that are generated in a plasma by an insulating film etching gas carbonyl sulfide (COS). When implanting sulfur, an appropriate value is set such that a concentration peak of sulfur (S) atoms appears within the polysilicon film 15, and not in a natural oxide film of the surface of the polysilicon film 15.

Next, as shown in FIG. 23, the natural oxide film of the surface is removed by the likes of wet etching, and then the first metal layer 16A (for example, tungsten nitride) and the second metal layer 16B (for example, tungsten) are deposited by a sputtering device or a CVD device. As a result, a stacked gate structure is formed.

Now, by inserting the first metal layer 16A (for example, tungsten nitride) between the polysilicon film 15 and the second metal layer 16B (for example, tungsten), a non-uniform silicide reaction between the polysilicon film 15 and the second metal layer 16B can be suppressed.

After this, the polysilicon film 15, the first metal layer 16A, and the second metal layer 16B undergo patterning and processing. Following this, well-known manufacturing steps of an ordinary semiconductor device are conducted, thereby manufacturing the semiconductor device of the structure shown in FIG. 21.

The above manufacturing method described the case of employing tungsten nitride (WN) in the first metal layer 16A, but the first metal layer 16A may be a metal nitride including as its main component any of tungsten (W), tantalum (Ta), molybdenum (Mo), niobium (Nb), iridium (Ir), ruthenium (Ru), and hafnium (Hf). Moreover, the metal material employed in the metal layer 16 may be a metal not including nitrogen provided it is a high melting point metal whose melting point is 2000° C. or more.

### Advantages

In the semiconductor device according to the present embodiment also, implanting sulfur atoms into the polysilicon film 15 results in Schottky barrier height between the metal layer 16 and the polysilicon film 15 becoming substantially zero. Moreover, interface resistance at the interface SA between the polysilicon film 15 and the first metal layer 16A depends exponentially on Schottky barrier height, hence by implanting sulfur to reduce Schottky barrier height, interface resistance can be significantly reduced. As a result, the semiconductor device according to the present embodiment makes it possible to lower resistance of the contact structure between the polysilicon film 15 and the first metal layer 16A.

### Other

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

For example, the above-described embodiments described atoms implanted into the silicon substrate 3 or the polysilicon film 15 as sulfur. However, similar advantages can be obtained even by implanting atoms of Group VI elements besides sulfur, such as selenium (Se), tellurium (Te), and polonium (Po). In addition, the semiconductor devices and manufacturing methods thereof shown in the above-described embodiments may be applied also to similar structures such as a volatile memory element of the likes of DRAM, or a CMOS logic circuit, system-on-chip (SOC), and so on. Moreover, the first embodiment described a contact structure including a source/drain region 8 which is an n type impurity diffusion region, taking as an example an n type transistor. Now, the contact plug need not necessarily be connected to the impurity diffusion region of the transistor. Similar advantages to those of the above-described embodiments can be displayed by implanting sulfur into the silicon substrate, even in the case of a structure where the contact plug and the silicon substrate contact unmediated by the n type impurity diffusion region.

What is claimed is:

1. A semiconductor device, comprising:
a gate insulating film formed on a semiconductor substrate;
a semiconductor layer formed on the gate insulating film; and
a first metal layer formed to be electrically connected to the semiconductor layer, 1×10¹⁹ atoms/cm³ or more of a Group VI element exists in an interface of the semiconductor layer and the first metal layer.

2. The semiconductor device according to claim 1, wherein
the Group VI element is sulfur.

3. The semiconductor device according to claim 1, wherein
the first metal layer contains nitrogen.

4. The semiconductor device according to claim 1, wherein
the first metal layer comprises:
a second metal layer electrically connected to the semiconductor layer; and
a third metal layer formed on the second metal layer.

5. The semiconductor device according to claim 1, wherein
the first metal layer is a high melting point metal whose melting point is 2000° C. or more.

6. The semiconductor device according to claim 1, further comprising a fourth metal layer formed to be electrically connected to the semiconductor substrate,
wherein 1×10¹⁹ atoms/cm³ or more of the Group VI element exists in an interface of the semiconductor substrate and the fourth metal layer.

7. The semiconductor device according to claim 6, wherein
the Group VI element is sulfur.

8. A semiconductor device, comprising:
a gate insulating film formed on a semiconductor substrate;
a semiconductor layer formed on the gate insulating film; and
a first metal layer formed to be electrically connected to the semiconductor layer,
a Group VI element existing in pairs at adjacent lattice positions of a lattice atomic structure in an interface of the semiconductor layer and the first metal layer.

9. The semiconductor device according to claim 8, wherein
the Group VI element is sulfur.

10. The semiconductor device according to claim 8, wherein
the first metal layer contains nitrogen.

11. The semiconductor device according to claim 8, wherein
the first metal layer comprises:
a second metal layer electrically connected to the semiconductor layer; and
a third metal layer formed on the second metal layer.

12. The semiconductor device according to claim 8, wherein
the first metal layer is a high melting point metal whose melting point is 2000° C. or more.

13. The semiconductor device according to claim 8, further comprising a fourth metal layer formed to be electrically connected to the semiconductor substrate,
wherein the fourth metal layer includes therein the Group VI element existing in pairs at the adjacent lattice positions of the lattice atomic structure in an interface of the semiconductor substrate.

14. The semiconductor device according to claim 13, wherein
the Group VI element is sulfur.

15. A manufacturing method of a semiconductor device, comprising:
implanting a Group VI element into a semiconductor layer to form 1×10¹⁹ atoms/cm³ or more of the Group VI element in an interface on the semiconductor layer; and
forming a first metal layer on the semiconductor layer.

16. The manufacturing method of a semiconductor device according to claim 15, wherein
the Group VI element is sulfur.

17. The manufacturing method of a semiconductor device according to claim 15, wherein
the first metal layer is formed by a metal material containing nitrogen.

18. The manufacturing method of a semiconductor device according to claim 15, wherein
the first metal layer is formed by a second metal layer electrically connected to the semiconductor layer and a third metal layer formed on the second metal layer.

19. The manufacturing method of a semiconductor device according to claim 15, wherein
the Group VI element is implanted into the semiconductor layer by ion implantation to form the Group VI element in the interface.
